(19) United States
(12) Patent Application Publication
(10) Pub. No.: US 2014/0353684 A1
(43) Pub. Date: Dec. 4, 2014

(54) SILICON CARBIDE EPITAXIAL WAFER AND METHOD FOR FABRICATING THE SAME

(71) Applicant: LG INNOTEK CO., LTD., Seoul (KR)

(72) Inventor: Moo Seong Kim, Seoul (KR)

(73) Assignee: LG INNOTEK CO., LD., Seoul (KR)

(21) Appl. No.: 14/369,921

(22) PCT Filed: Dec. 13, 2012
(86) PCT No.: PCT/KR2012/010865

§ 371 Date: Jun. 30, 2014

(30) Foreign Application Priority Data
Dec. 28, 2011 (KR) 10-2011-0144927

(51) Int. Cl. H01L 21/02; C30B 25/14; C30B 29/36; H01L 29/16

(52) U.S. Cl. CPC H01L 21/02529; H01L 21/02378; H01L 21/02634; H01L 29/1608; C30B 25/14; C30B 29/36
USPC 257/77; 117/88

(57) ABSTRACT

A method for fabricating a silicon carbide epitaxial wafer according to the embodiment includes introducing a carbon source and a silicon source into a reactor in which a silicon carbide wafer is provided; heating the reactor; and adjusting an amount of the silicon source or the carbon source introduced into the reactor. A silicon carbide epitaxial wafer according to the embodiment includes a silicon carbide epitaxial layer having a surface roughness of 0.3 nm or less.

### TECHNICAL FIELD

The embodiment relates to a silicon carbide epitaxial wafer and a method for fabricating the silicon carbide epitaxial wafer.

### BACKGROUND ART

In general, among technologies to form various thin films on a substrate or a wafer, a CVD (Chemical Vapor Deposition) scheme has been extensively used. The CVD scheme results in a chemical reaction. According to the CVD scheme, a semiconductor thin film or an insulating layer is formed on a wafer surface by using the chemical reaction of a source material.

The CVD scheme and the CVD device have been spotlighted as an important thin film forming technology due to the fineness of the semiconductor device and the development of high-power and high-efficiency LED. Recently, the CVD scheme has been used to deposit various thin films, such as a silicon layer, an oxide layer, a silicon nitride layer, a silicon oxynitride layer, or a tungsten layer, on a wafer.

When the SiC epitaxial layer is grown on the substrate or the wafer, defects formed in an interior or a surface of a thin film may exert an influence upon the performance and long-term reliability of a power device. In addition, in order to improve the productivity, various schemes have been developed to shorten the process time by increasing the growth rate.

According to the related art, the amount of Si gas is increased in the high-temperature environment to induce the high growth rate and Cl-based gas is introduced to reduce the secondary defect caused by the Si gas such that the diffusion distance can be adjusted in match with the chemical stoichiometry at the surface of the wafer.

However, the high growth temperature, the introduction of the Cl-based gas and a process for inserting a buffer layer may additionally require the secondary process to reduce the defects in the epitaxial layer growth process. Due to the additional secondary process, the whole process becomes complicated, the cost is increased, and the quality of the substrate surface is deteriorated.

Therefore, a method of growing an epitaxial layer, capable of increasing the growth rate and removing surface defects without requiring the secondary process is necessary.

### DISCLOSURE OF INVENTION

### Technical Problem

The embodiment provides a silicon carbide epitaxial wafer and a method of fabricating the silicon carbide epitaxial wafer, which can increase the growth temperature and reduce the defects by inducing the reaction through the adjustment of an amount of carbon and Si gas without requiring the secondary process, such as an insertion of a buffer layer.

### Solution to Problem

According to the embodiment, there is provided a method for fabricating a silicon carbide epitaxial wafer, the method including introducing a carbon source and a silicon source into a reactor in which a silicon carbide wafer is provided; heating the reactor; and adjusting an amount of the silicon source or the carbon source introduced into the reactor.

A silicon carbide epitaxial wafer according to the embodiment includes a silicon carbide epitaxial layer having a surface roughness of 0.3 nm or less.

### Advantageous Effects of Invention

The method for fabricating the silicon carbide epitaxial wafer according to the embodiment repeats the steps of introducing a greater amount of the silicon source and a smaller amount of the silicon source in a predetermined period to form the silicon carbide epitaxial layer on the wafer. That is, reaction gas can be repeatedly generated in the reactor in a carbon-rich state or a silicon-rich state.

Since the carbon source or the silicon source is repeatedly introduced in a predetermined period by adjusting the amount of the carbon source or the silicon source, the stress of the epitaxial layer caused by the difference in partial bonding energy when the silicon carbide epitaxial layer is deposited on the wafer can be compensated, so that the silicon carbide epitaxial layer having the high quality can be deposited on the wafer.

That is, the silicon carbide epitaxial wafer fabricated through the above method may include the epitaxial layer having reduced surface defects and surface roughness, the silicon carbide epitaxial layer having the high quality can be fabricated.

### BRIEF DESCRIPTION OF DRAWINGS

FIG. 1 is a flowchart showing a method for fabricating a silicon carbide epitaxial wafer according to the embodiment.

### MODE FOR THE INVENTION

In the description of the embodiments, it will be understood that, when a layer (or film), a region, a pattern, or a structure is referred to as being “on” or “under” another substrate, another layer (or film), another region, another pad, or another pattern, it can be “directly” or “indirectly” on the other substrate, layer (or film), region, pad, or pattern, or one or more intervening layers may also be present. Such a position of the layer has been described with reference to the drawings.

The thickness and size of each a layer (or film), each region, each pattern, or each structure shown in the drawings may be exaggerated, omitted or schematically drawn for the purpose of convenience or clarity. In addition, the size of elements does not utterly reflect an actual size.

Hereinafter, a silicon carbide epitaxial wafer and a method for fabricating the same according to the embodiment will be described with reference to the accompanying drawing.

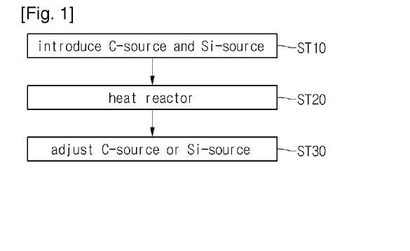

Referring to FIG. 1, the method for fabricating the silicon carbide epitaxial wafer according to the embodiment includes the steps of introducing a carbon source and a silicon source into a reactor (ST10); heating the reactor (ST20); and adjusting an amount of the carbon source or the silicon source (ST30).

In step ST10 of introducing the carbon source and the silicon source into the reactor, reaction gas may be introduced into the reactor in which a silicon carbide wafer is provided. The reaction gas may include the carbon source and the silicon source. For instance, a precursor of the reaction gas may include a liquid raw material, such as methylchlorosilane (MTS), and a gaseous raw material, such as silane (SiH4) and ethylene (C2H4) or silane (SiH4) and propane (C3H8). However, the embodiment is not limited thereto, and various precursors including carbon and silicon can be employed as the precursor of the carbon source or the silicon source.

Then, in step ST20 of heating the reactor, the reactor is heated to the deposition temperature of the silicon carbide epitaxial layer. For instance, the growth temperature may be in the range of 1500° C. to 1700° C. In the above growth temperature, the reaction gas introduced into the reactor is ionized and decomposed into an intermediate compound and the intermediate compound reacts with the substrate or the wafer provided in the reactor so that the silicon carbide epitaxial layer is deposited on the substrate or the wafer. For instance, the intermediate compound may include CHx?(1≦x≦4) or SiClx?(1≦<x<4) having CH3?, SiCl?, SiCl2?, SiHCl?, or SiHCl2.

In step ST30 of adjusting the amount of the carbon source or the silicon source, the amount of the reaction gas introduced into the reactor is adjusted. Preferably, the amount of the silicon source in the reaction gas may be adjusted.

According to the method for fabricating the silicon carbide epitaxial wafer of the embodiment, the steps of introducing a greater amount of the silicon source and a smaller amount of the silicon source may be repeated. That is, in a state that the amount of the carbon source is fixed, the steps of introducing a greater amount of the silicon source and a smaller amount of the silicon source may be repeated in a predetermined period.

The method for fabricating the silicon carbide epitaxial wafer according to the embodiment includes the step of adjusting the amount of the carbon source or the silicon source introduced into the reactor. For instance, the method may include a first step of increasing the amount of the silicon source and a second step of reducing the amount of the silicon source. A greater amount of the silicon source is introduced in the first step and a smaller amount of the silicon source is introduced in the second step.

In addition, the first and second steps may be repeated in a predetermined period. Thus, the silicon source is not uniformly introduced, but a greater amount of the silicon source and a smaller amount of the silicon source are repeatedly introduced in a predetermined period.

Further, the first and second steps can be repeatedly performed during the whole deposition process or during some period of the deposition process.

For instance, when the silane and propane are introduced as the precursor, the amount of the silane may be greater or smaller than the amount of the propane. Therefore, since the amount of the silane serving as the silicon source including the silicon is adjusted, the molar ratio of the carbon and silicon in the reactor can be adjusted.

According to the method for depositing the silicon carbide of the embodiment, when the reaction gas including the carbon source and the silicon source is introduced, the molar ratio (C/Si) of the carbon and silicon in the reactor may be in the range of 0.8 to 1.8. That is, the reactor may be kept in the carbon-rich state or the silicon-rich state. In this state, if the greater amount of the silicon source and the smaller amount of the silicon source are repeatedly introduced into the reactor in a predetermined period, the molar ratio of the carbon and silicon in the reactor may be changed by the range of 0.1 to 0.5. Preferably, the molar ratio of the carbon and silicon in the reactor may be changed by the range of 0.1 to 0.3.

That is, the atmosphere in the reactor may be repeatedly changed into the carbon-rich state and the silicon-rich state. For this reason, a buffer layer serving as a buffer before the silicon carbide epitaxial layer is deposited may be deposited on the wafer placed in the reactor, so the silicon carbide epitaxial layer can be deposited on the buffer layer in a state that the molar ratio of the carbon and silicon is 1:1.

Therefore, the silicon carbide epitaxial layer is deposited on the buffer layer formed on the wafer, so the deposition process can be performed while compensating for the stress caused by the difference in partial bonding energy, so that the high-quality silicon carbide epitaxial wafer having no defects can be fabricated.

In addition, the first and second steps may be repeated in the period of about 3 seconds to about 30 seconds to introduce the greater amount of the silicon source and the smaller amount of the silicon source. If the period is less than 3 seconds, the effect of the buffer layer may not be obtained. In addition, if the period exceeds 30 seconds, an epitaxial layer having a multi-structure is formed on the silicon carbide wafer, causing another defect. Preferably, the first and second steps may be repeated in the period of about 5 seconds to about 10 seconds to introduce the greater amount of the silicon source and the smaller amount of the silicon source.

The first and second steps can be repeatedly performed during the whole deposition process for the epitaxial layer or during some period of the deposition process for the epitaxial layer. In the case of latter, the silicon source may be uniformly introduced in the remaining period of the deposition process for the epitaxial layer.

According to the embodiment, the amount of the carbon source is fixed to the predetermined level and the amount of the silicon source is periodically changed. However, it is also possible to periodically change the amount of the carbon source while fixing the amount of the silicon source.

That is, the method may include the first step of increasing the amount of the carbon source and the second step of reducing the amount of the carbon source introduced into the reactor to change the molar ratio of the carbon and silicon in the reactor. In this case, the amount of the liquid raw material, such as methylchlorosilane (MTS), serving as the precursor of the reaction gas may be adjusted.

However, the embodiment is not limited to the above. For instance, the amount of the silicon source and the amount of the carbon source may be simultaneously changed to change the molar ratio of the carbon and silicon in the reactor.

According to the method for fabricating the silicon carbide epitaxial wafer of the embodiment, the first step of introducing a greater amount of the silicon source and/or the carbon source and the second step of introducing a smaller amount of the silicon source and/or the carbon source are repeated in a predetermined period such that the buffer layer can be substantially formed on the wafer. Thus, the silicon carbide epitaxial layer can be deposited on the wafer in a state that the molar ratio of the carbon and silicon is 1:1.

As described above, since the silicon source is repeatedly introduced by adjusting the amount of the silicon source, the crystal growth can be achieved while compensating for the stress caused by the difference in partial bonding energy, so that the silicon carbide epitaxial layer having the high quality can be deposited on the wafer. That is, the silicon carbide epitaxial layer fabricated through the above method has the reduced surface defect and the surface roughness in the epitaxial layer, the silicon carbide epitaxial layer having the high quality can be fabricated.

In particular, the atmosphere of the carbon and silicon in the reactor, that is, the molar ratio of the carbon and silicon can be changed by the range of 0.1 to 0.5 through the first and second steps, and the first and second steps can be repeatedly performed in the period of 5 seconds to 10 seconds. In this case, the silicon carbide epitaxial layer deposited on the wafer has no surface defect, such as the basal dislocation, and may have the surface roughness of 0.3 nm or less, so that the silicon carbide epitaxial layer having the high quality can be fabricated.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. A method for fabricating a silicon carbide epitaxial wafer, the method comprising:
introducing a reaction gas into a reactor in which a silicon carbide wafer is provided;
heating the reactor; and
adjusting an amount of the reaction gas introduced into the reactor.

2-5. (canceled)

6. The method of claim 1, wherein the reaction gas includes a silicon source or a carbon source.

7. The method of claim 6, wherein the adjusting of the amount of the reaction gas comprises:
increasing the amount of the silicon source; and
reducing the amount of the silicon source.

8. The method of claim 7, wherein, in the adjusting of the amount of the reaction gas, a molar ratio of the silicon source and the carbon source is changed by a range of 0.1 to 0.5.

9. The method of claim 7, wherein, in the adjusting of the amount of the reaction gas, a molar ratio of the silicon source and the carbon source is changed by a range of 0.1 to 0.3.

10. The method of claim 6, wherein the adjusting of the amount of the reaction gas comprises:
increasing the amount of the carbon source; and
reducing the amount of the carbon source.

11. The method of claim 10, wherein, in the adjusting of the amount of the reaction gas, a molar ratio of the silicon source and the carbon source is changed by a range of 0.1 to 0.5.

12. The method of claim 10, wherein, in the adjusting of the amount of the reaction gas, a molar ratio of the silicon source and the carbon source is changed by a range of 0.1 to 0.3.

13. The method of claim 6, wherein the adjusting of the amount of the reaction gas comprises:
increasing the amount of the silicon source and the carbon source; and
reducing the amount of the silicon source and the carbon source.

14. The method of claim 13, wherein, in the adjusting of the amount of the reaction gas, a molar ratio of the silicon source and the carbon source is changed by a range of 0.1 to 0.5.

15. The method of claim 13, wherein, in the adjusting of the amount of the reaction gas, a molar ratio of the silicon source and the carbon source is changed by a range of 0.1 to 0.3.

16. A silicon carbide epitaxial wafer fabricated through the method of claim 1 including a silicon carbide epitaxial layer having a surface roughness of 0.3 nm or less.

17. A silicon carbide epitaxial wafer fabricated through the method of claim 6 including a silicon carbide epitaxial layer having a surface roughness of 0.3 nm or less.

18. A silicon carbide epitaxial wafer fabricated through the method of claim 7 including a silicon carbide epitaxial layer having a surface roughness of 0.3 nm or less.

19. A silicon carbide epitaxial wafer fabricated through the method of claim 10 including a silicon carbide epitaxial layer having a surface roughness of 0.3 nm or less.

20. A silicon carbide epitaxial wafer fabricated through the method of claim 13 including a silicon carbide epitaxial layer having a surface roughness of 0.3 nm or less.
